(19) United States
(12) Patent Application Publication
(10) Pub. No.: US 2010/0139768 A1
(43) Pub. Date: Jun. 10, 2010

(54) HEAT SPREADING SHIELD

(75) Inventors: Michael Milbourne, Los Altos, CA (US); Evan Green, San Jose, CA (US); Mark McDonald, Milpitas, CA (US)

Correspondence Address: THE MUELLER LAW OFFICE, P.C., 12951 Harwick Lane, San Diego, CA, 92130, US

(73) Assignee: SOLFOCUS, INC., Mountain View, CA (US)

(21) Appl. No.: 12/548,410

(22) Filed: Aug. 26, 2009

Related U.S. Application Data
(60) Provisional application No. 61/121,539, filed on Dec. 10, 2008.

(51) Int. Cl. H01L 31/00

(52) U.S. Cl. 136/259

(57) ABSTRACT

The present invention is a heat conducting system for a solar energy device. The system includes a shield made of a heat conducting material that conforms to the convex side of a hollow curved mirror in a solar energy device. The present invention may reduce the temperature differential over an area of the mirror via passive heat conduction. The conductance of the shield of this invention is greater than the conductance of the mirror. The shield may be a layer of metal such as a metal tape. The tape may be applied as one or more strips that have ends which are separated by a seam or gap. The ends of the strips may be oriented in the same direction in an array of mirrors in a manner that provides for minimal exposure to concentrated solar irradiation at the gap or seam.

### RELATED APPLICATION

This application claims priority to U.S. Provisional Patent Application 61/121,539 filed Dec. 10, 2008 entitled “Inner Diameter Shield for a Mirror in a Solar Energy Device”, which is hereby incorporated by reference as if set forth in full in this application for all purposes.

### BACKGROUND OF THE INVENTION

It is generally appreciated that one of the many known technologies for generating electrical power involves the harvesting of solar radiation and its conversion into direct current (DC) electricity. Solar power generation has already proven to be a very effective and “environmentally friendly” energy option, and further advances related to this technology continue to increase the appeal of such power generation systems. In addition to achieving a design that is efficient in both performance and size, it is also desirable to provide solar power units that are characterized by reduced cost and increased levels of mechanical robustness.

Solar concentrators are solar energy systems which increase the efficiency of conversion of solar energy to DC electricity. Solar concentrators utilize, for example, parabolic mirrors and Fresnel lenses for focusing the incoming solar energy, and heliostats for tracking the sun's movements in order to maximize light exposure. One type of solar concentrator, disclosed in U.S. Patent Publication No. 2006/0266408, entitled “Concentrator Solar Photovoltaic Array with Compact Tailored Imaging Power Units” utilizes a front panel for allowing solar energy to enter the assembly, with a primary mirror and a secondary mirror to reflect and focus solar energy through an optical receiver, also referred to as a non-imaging concentrator, onto a photovoltaic (PV) cell (also known as a solar cell). The surface area of the PV cell in such a system is much smaller than what is required for non-concentrating systems, for example less than 1% of the entry window surface area. Such a system has a high efficiency in converting solar energy to electricity due to the focused intensity of sunlight. The mirror system generally concentrates sunlight by 500 times or more.

A tracker may be used to properly align the concentrator so that solar irradiation is accurately reflected onto the solar cell. In the event of tracker malfunction or misalignment of the solar energy concentrator, concentrated sunlight may be partially directed to the surface of the primary mirror rather than the PV cell. Concentrated sunlight on the surface of a mirror may result in a significant thermal gradient in the body of the mirror. This may result in damage to the mirror such as warpage, cracking or breakage. Clearly, mirrors are significant components of a solar concentrator system that require protection. Devising more cost-effective methods to protect mirrors from concentrated sunlight will contribute to the reliability of a solar concentrator design.

### SUMMARY OF THE INVENTION

The present invention is a heat conducting system for a solar energy device. The system includes a shield made of a heat conducting material that conforms to the convex side of a curved mirror in a solar energy device. The mirror may have a bowl shape with a diameter-to-depth aspect ratio greater than 50. The mirror may be less than 5 mm thick. The shield of this invention may be disposed on a region around an aperture in the mirror and protect the mirror from the effects of concentrated solar radiation by reducing thermal gradients on the mirror. The shield may provide a pathway for reducing the temperature differential over an area of the mirror via passive heat conduction while remaining thermally isolated from the PV cell. The conductance of the shield of this invention is greater than the conductance of the mirror. The shield may be placed on the non-reflective surface of the mirror, and may be thermally isolated from the photovoltaic cell of the solar energy system. Heat generated by concentrated sunlight may be transferred from the mirror to the shield via direct irradiation or thermal conduction to the underside of the mirror.

In one embodiment, the shield may be a layer of metal located on the convex side of the mirror. The shield may be affixed by any method such as with an adhesive or by thermal/plasma spraying. The shield may be metal tape that may be applied as one or more strips. In one embodiment the shield may be applied in one or more strips that have ends which are separated by a seam or gap. The ends of the strips may be oriented in the same direction in an array of mirrors in a manner that provides for minimal exposure to concentrated solar irradiation at the gap or seam.

### BRIEF DESCRIPTION OF THE DRAWINGS

FIG. 1A is a cross section of a solar energy device showing on-axis and off-axis irradiation. FIG. 1B depicts a close up cross section of a portion of the solar energy device with a heat shield.

FIG. 2 shows top side and bottom side views of a heat shield of this invention.

FIG. 3 shows an exploded view of one embodiment of the heat shield of this invention.

FIG. 4A shows a rear view of an array of mirrors on a module. FIG. 4B shows a close-up of two embodiments of the shield of this invention indicating the orientation of gaps or seams between the ends of the shield strips.

### DETAILED DESCRIPTION OF THE EMBODIMENTS

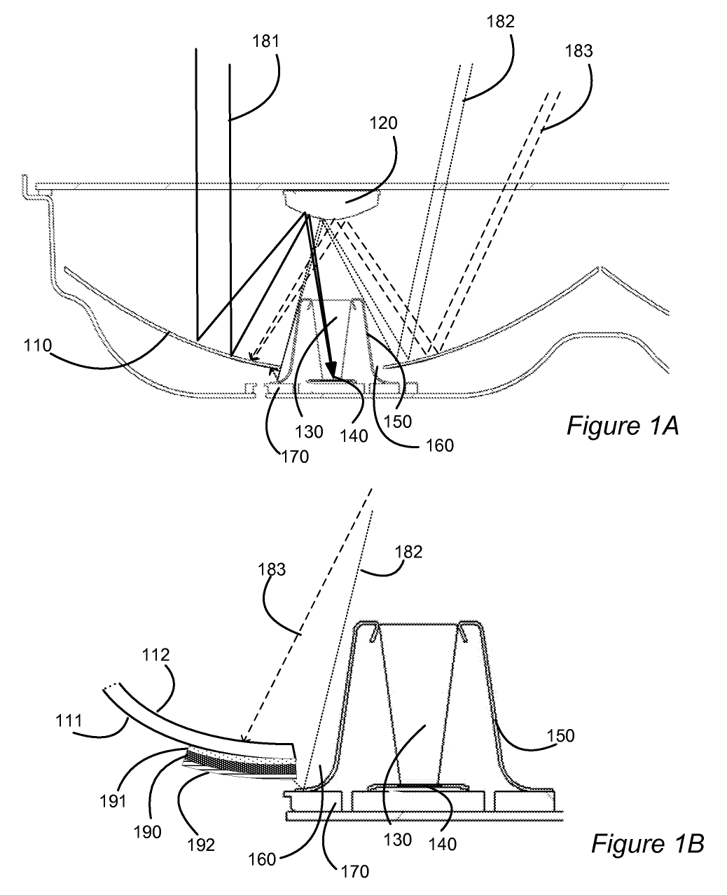

Reference will now be made in detail to embodiments of the disclosed invention, one or more examples of which are illustrated in the accompanying drawings. The shield of this invention may protect the primary mirror and other components of a concentrating solar energy device. One type of concentrating solar energy device shown in FIG. 1 utilizes a curved shell primary mirror 110 and a secondary mirror 120 to concentrate and focus solar energy to an optical non-imaging concentrator 130, which directs concentrated solar radiation onto a photovoltaic (PV) cell 140. The concentrator may be housed in a receiver module 150. The receiver module 150 may be located in an aperture 160, which in this illustration is centrally located, in the hollow primary mirror 110 and serve to protect the PV cell housing 170 from concentrated solar radiation. When the solar energy device is directed along the axis of incoming solar radiation 181, concentrated sunlight is properly directed onto the non-imaging concentrator 130. From there, the light is directed to a PV cell 140 for conversion into useable electrical energy. The concentrating solar energy device of FIG. 1 may be, for example, the device disclosed in U.S. Patent Publication No. 2006/0266408, entitled “Concentrator Solar Photovoltaic Array with Compact Tailored Imaging Power Units”, which is hereby incorporated by reference. The device may be assembled into an array of devices and mounted on a tracking device so that they are directed along a path that is normal to the sun's irradiation.

The shield device of this invention may protect the primary mirror from concentrated solar radiation caused by off-axis irradiation of the solar energy device. Off-axis irradiation 182, 183 may occur for any reason, for example when the solar energy device is misaligned or when the movement of the solar energy device is mistimed. Other sources of off-axis radiation include the partial or complete failure of the solar tracking device. Off-axis irradiation onto the primary mirror is distinct from heat build-up in the PV cell 140 and may result in a strong temperature differential over an area of the mirror where a focused beam of concentrated sunlight is directed. The heat shield of this invention may be separate from any temperature control device that may be thermally coupled to the PV cell. A temperature differential on the mirror may lead to warping or cracking of the mirror as a localized area experiences a strong thermal gradient. The shield device 190 of this invention, as shown in FIG. 1B, may reduce temperature gradients that are produced when concentrated sunlight is directed to the mirror. The more uniform temperature assures a more uniform stress, which in turn reduces the risk of exceeding the elastic limit or fracture strength of the mirror material. In one embodiment of this invention, this shield may reduce the temperature gradient over an area caused by concentrated irradiation on a small portion of the mirror by conducting the thermal energy over a wider area. This may advantageously improve the lifetime of the mirror by providing a mechanism for heat conduction with a material of higher thermal conductance (e.g. metal) relative to the low thermal conductance of commonly used mirror materials (e.g. glass, or plastic).

FIGS. 1A and 1B illustrate a mechanism for heat build build-up in a mirror. Due to various tracker and misalignment errors as described above, a solar energy system may be oriented slightly off the axis normal to the sun's rays which may allow incident radiation 182 to be directed toward a space between the receiver shield 150 and the mirror 110, causing a localized ‘hot spot’ to occur on the convex side 111 of the mirror 110. A second example of heat build up occurs when the degree of off-axis orientation is more pronounced 183 causing a larger deviation in the focused solar irradiation to a point somewhere on the concave side 112 of the primary mirror 110. These points of focused irradiation generate a strong increase in the temperature of a small portion of the mirror. It is the gradient in temperature between the irradiated area and the surrounding portion of the mirror which may cause the mirror to break, crack or warp. The likelihood of mirror damage is increased as the temperature of the irradiated portion is raised and when thinner mirror materials (e.g. less than 5 mm) are used. The shield of this invention may act to reduce the temperature gradient formed on a mirror from concentrated solar irradiation.

The shield of this invention 190 is a heat conductive layer which may be disposed on the convex side 111 of the hollow primary mirror 110, substantially surrounding the opening 160 of the mirror 110. The shield of this invention is in thermal contact with the mirror. In one embodiment, the shield 190 may be affixed with an adhesive layer 191 (e.g. acrylic, acrylate, epoxy, silicone, or other adhesive) to the mirror 110. The adhesive may have heat conduction properties. In another embodiment the heat shield 190 may include an outer layer of material 192 such as a polymer or paint coating (e.g. acrylic) that may improve the emissivity or durability properties of the shield. The polymer layer 192 may be transparent in the visible and near IR region of the spectrum to provide optimum emissivity of thermal energy. The outer layer 192 may be highly reflective or highly emissive. The outer layer may be more emissive than the base material of the shield. In one embodiment, the outer layer 192 may have a white finish.

The shield 190 may be made of any material such as a metal (e.g., Al, Cu, Ag, steel, and Au) that effectively conducts heat. The term conductance for the purposes of this disclosure is a function of at least the thermal conductivity of a material and the thickness of the component. The shield device of this invention may be any thickness that provides for a thermal conduction level, or conductance, that is higher than the thermal conduction level of the mirror. Metal tapes provide high conductivity values allowing for excellent conduction properties from relatively low thicknesses. In one embodiment of this invention the shield may one or more strips of metal tape such as 3M™ aluminum tape. The shield may be any width that provides for the conductance to be sufficient to reduce a temperature gradient in a mirror to below the fracture point of the mirror material. In one non-limiting example, the shield of this invention may reduce a thermal gradient in a mirror from 10° C./mm to 5° C./mm. The shield of this invention advantageously provides for reduction of a thermal gradient in curved mirrors with high aspect ratios comprised of a thin material (less than 5 mm thick). Such ‘hollow’ curved mirrors are not solid optical elements and may be unable to adequately conduct heat away from thermal gradients greater than 5° C./mm. The mirror material may be have an aspect ratio (diameter/depth) greater than 50 and be comprised of a thin material (less than 5 mm thick). In one embodiment, the mirror material may be about 2 mm thick. The shield of this invention may reduce the temperature of a localized region of the mirror from more than 100° C. to less than 65° C. In one embodiment the shield may be 1-100 mm wide, for example 25 mm wide. The shield may be between 1 and 1,000 μm thick, for example between 70 and 500 μm thick. The shield may be applied as one or more strips of tape with a seam or gap between the ends of the tape. This may advantageously improve the application of the tape onto the curved geometry of the primary mirror. In one embodiment the tape may be applied in two or more sections to conform to a compound curve of a curved mirror. In an alternative embodiment, the shield may be a stamped metal disk affixed to the mirror to surround the opening. The shield may be a stamped metal disk of varying thickness to conform to a curved mirror and affixed by an adhesive. Note that while embodiments of the shield are depicted as annular rings in this disclosure, other configurations are possible such as polygonal or curvilinear shapes, which may be designed to achieve the desired thermal profiles across the surface area of the shield.

In other embodiments, the shield may be a layer of thermal or plasma sprayed conductive material such as a metal (e.g. Al, Cu). In one embodiment the shield may have an apodized or smoothed edge to provide a gradient of thickness of the shield material near an edge of the shield. A slowly varying thickness may advantageously avoid a spatial gradient in the conductance, and decrease the risk of damage to the mirror at the edge of the shield. Another benefit of providing an apodized edge may be that the volume of metal sprayed could be reduced compared to a spraying of uniform thickness, resulting in a reduced manufacturing cost.

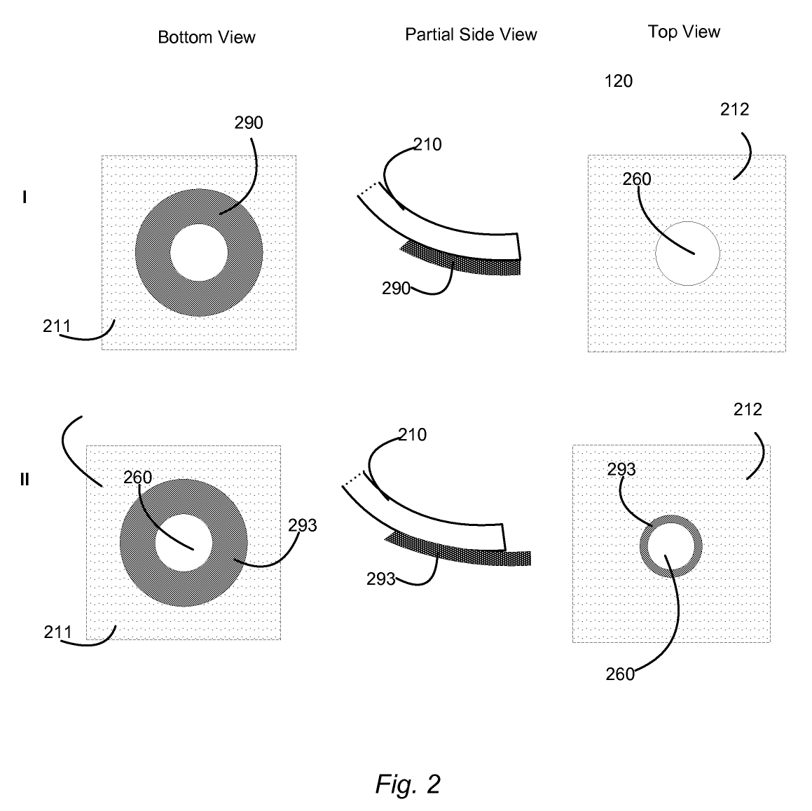

An advantage of the device of this invention is shown in Example I of FIG. 2. The shield 290 on the convex side 211 of the mirror (Bottom View), may effectively conduct heat away from a high temperature area of the mirror while the reflective surface of the concave side mirror 212 is not blocked or reduced (Top View). It can also be seen that the mirror aperture 260 is substantially uncovered by the shield, advantageously isolating the heat regulation mechanism associated with the PV cell from the heat conduction means of this invention. In one embodiment of this invention shown in Example II of FIG. 2, the shield 293 may overhang the aperture 260 of the mirror to provide additional protection from concentrated sunlight to any components of the solar energy system disposed below the mirror aperture 260 while remaining separate from the solar cell. In this embodiment, the solar cell and receiver components (not shown) may be thermally isolated from the shield device of this invention, for example through physical separation or presence of a thermally insulative material.

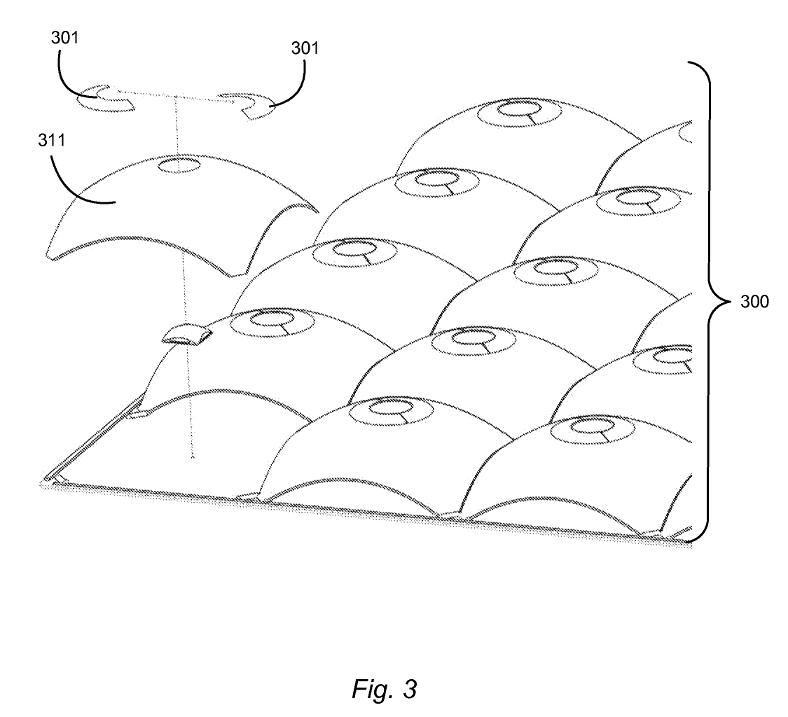

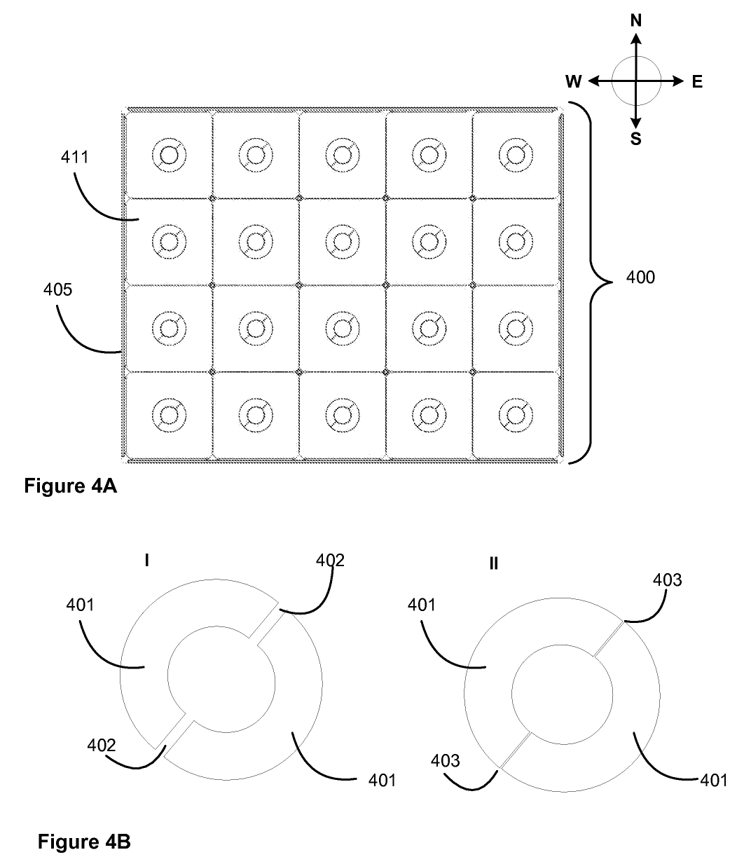

FIG. 3 illustrates one embodiment of this invention in which the shield may be one or more strips 301 of metallic tape, for example two semi-circular pieces arranged end to end and applied to the convex side of the primary mirror 311 in an array 300 of primary mirrors. The tape may be applied in one or more strips to accommodate smooth application to the compound curve of a curved primary mirror. The ends of the strips may meet at a seam or a gap between the strips and may be oriented substantially identically on the mirrors 311 in an array 300. In some embodiments, the gap or seam may be less than 1 inch wide. FIG. 4A shows a rear view of an array of primary mirrors 400. In embodiments of this invention (detailed in FIG. 4B), the space between the ends of the metallic strips of this invention may be a gap 402 (“I” of FIG. 4B) or a seam 403 (“II” of FIG. 4B). The ends of the metallic strips may be oriented in the same direction for all of the mirrors 411 arrayed in a module 400 relative to a side of the module 405, as shown in FIG. 4A. The location and the orientation of the ends of the metallic strips may provide for reduced exposure of unprotected regions of the mirror to hot spots caused by off-axis irradiation of the concentrated solar energy system. Hot spots may occur in an east-west orientation on the primary mirror as the system tracks along the path of the sun when the off-axis error is caused by a delay or an advance of the tracking timing. Hot spots may occur in a north-south orientation on the primary mirror as the system tracks along the path of the sun when the off-axis error is caused by a lateral shift of the tracking system. In one embodiment of this invention, the gap or seam between the ends of the one or more shield strips may be oriented around a 43-47° angle relative to the side 405 of an array of primary mirrors 411. In another embodiment of this invention, the gap or seam between the ends of one or more shield strips may be oriented around a 43-47° angle relative to the east-west path of the sun. These orientations may advantageously minimize the occurrence of hot spots on the ends of the metallic shield strips.

While the specification has been described in detail with respect to specific embodiments of the invention, it will be appreciated that those skilled in the art, upon attaining an understanding of the foregoing, may readily conceive of alterations to, variations of, and equivalents to these embodiments. These and other modifications and variations to the present invention may be practiced by those of ordinary skill in the art, without departing from the spirit and scope of the present invention, which is more particularly set forth in the appended claims. Furthermore, those of ordinary skill in the art will appreciate that the foregoing description is by way of example only, and is not intended to limit the invention. Thus, it is intended that the present subject matter covers such modifications and variations as come within the scope of the appended claims and their equivalents.

What is claimed is:

1. A heat conducting system for a solar energy device comprising:
a hollow curved mirror having a convex side, a concave side, an aperture and a first conductance;
a shield conforming to the convex side of the mirror and surrounding a portion of the opening, the shield having a second conductance; and
a photovoltaic cell for converting solar radiation into electrical energy;
wherein the second conductance of the shield is greater than the first conductance of the mirror, and wherein the shield is thermally isolated from the photovoltaic cell.

2. The heat conducting system of claim 1 wherein the shield is comprised of metal tape.

3. The heat conducting system of claim 1 wherein the hollow curved mirror has a thickness less than 5 mm.

4. The heat conducting system of claim 1 wherein the shield is comprised of a stamped metal disk having an aperture.

5. The heat conducting system of claim 1 wherein the shield is comprised of a layer of material affixed to the mirror by thermal spraying.

6. The heat conducting system of claim 2 wherein the metal tape is comprised of one or more strips surrounding the aperture, wherein the strips have ends.

7. The heat conducting system of claim 6 wherein the ends of the metal strips are separated by a gap or seam.

8. The heat conducting system of claim 6 further comprising an array of solar energy devices, wherein sides of the array are oriented relative to the axis of the sun's rays, and wherein the ends of the tape are oriented to minimize off-axis irradiation impinging at the ends.

9. The heat conducting of system of claim 7, wherein the gap or seam is less than 1 inch wide.

10. The heat conducting system of claim 8 wherein the ends of the metal tape are oriented at a 43°-47° angle relative to a side of the array of solar energy devices.

11. The heat conducting system of claim 2 wherein the metal tape is comprised of a metal selected from the group consisting of aluminum, silver, gold, copper, steel and iron.

12. The heat conducting system of claim 2 wherein the metal tape is affixed to the mirror with an adhesive.

13. The heat conducting system of claim 1 wherein the shield overhangs the aperture.

14. The heat conducting system of claim 1 wherein the shield further comprises a polymer layer.

15. The heat conducting system of claim 14 wherein the polymer layer has a higher thermal emissivity than the shield.

16. The heat conducting system of claim 1 wherein the shield has a thickness which smoothly decreases toward an edge of the shield.

17. A method for reducing the temperature differential over a portion of a concentrating solar mirror comprising:
providing a hollow curved mirror and a photovoltaic cell, wherein the mirror comprises a concave side, a convex side, and an aperture; and
fixing a shield to a portion of the convex side of the mirror;
thermally isolating the shield from the photovoltaic cell;
wherein the shield comprises a heat conducting material surrounding a portion of the opening conforming to the shape of the curved mirror.

18. The method claim 17 wherein the heat conducting material comprises a metal tape.

19. The method claim 17 wherein the metal tape comprises one or more strips separated by a gap.

20. The method claim 17 wherein the gap is oriented at a 43°-47° angle relative to the path of the sun.
